(19) United States
(12) Patent Application Publication
(10) Pub. No.: US 2014/0341682 A1
(43) Pub. Date: Nov. 20, 2014

(54) SUBSTRATE PROCESSING MODULE AND SUBSTRATE PROCESSING APPARATUS INCLUDING THE SAME

(71) Applicant: EUGENE TECHNOLOGY CO., LTD., Gyeonggi-do (KR)

(72) Inventors: Il-Kwang Yang, Gyeonggi-do (KR); Gyoung-Gyu Song, Gyeonggi-do (KR); Kyong-Hun Kim, Gyeonggi-do (KR); Yong-Ki Kim, Chungcheongnam-do (KR); Yang-Sik Shin, Gyeonggi-do (KR)

(73) Assignee: EUGENE TECHNOLOGY CO., LTD., Gyeonggi-do (KR)

(21) Appl. No.: 14/370,045

(22) PCT Filed: Nov. 23, 2012
(86) PCT No.: PCT/KR2012/009955

§ 371 Date: Jun. 30, 2014

(30) Foreign Application Priority Data
Feb. 16, 2012 (KR) 10-2012-0015735

(51) Int. Cl. H01L 21/677; H01L 21/683

(52) U.S. Cl. CPC H01L 21/677; H01L 21/683
USPC 414/226.05

(57) ABSTRACT

Provided is a substrate processing module. The substrate processing module includes a lower chamber having an opened upper portion, the lower chamber having a passage, through which a substrate is accessible, in a side thereof, a plurality of susceptors on which the substrate is placed on each of top surfaces thereof, the plurality of susceptors being disposed within the lower chamber and fixedly disposed around a preset center of the lower chamber, a rotation member disposed on the preset center of the lower chamber, the rotation member being rotatable with respect to the preset center, a plurality of holders connected to the rotation member and rotated together with the rotation member, the plurality of holders having at least one seat surface on which the substrate is placed, and a driving module connected to the rotation member, the driving module moving one of the holders to a transfer position corresponding to the passage by driving the rotation member.

### BACKGROUND OF THE INVENTION

The present invention disclosed herein relates to a substrate processing module and a substrate processing apparatus including the same, and more particularly, to a substrate processing module including a plurality of susceptors and a substrate processing apparatus including the same.

A semiconductor device includes a plurality of layers on a silicon substrate. The layers are deposited on the substrate through a deposition process.

The substrate is loaded on a susceptor disposed within a process chamber. The deposition process is performed within the process chamber. Here, the substrate processing apparatus may be classified into a single wafer type and a batch type according to the number of loaded substrate. In case of the single wafer type substrate processing apparatus, one substrate is loaded into a process chamber, and then, a deposition process is performed on the one substrate. On the other hand, in case of the batch type substrate processing apparatus, a plurality of substrates are loaded into a process chamber, and then a deposition process is performed on the plurality of substrates at the same time.

### SUMMARY OF THE INVENTION

The present invention provides a substrate processing module which performs a process on a plurality of substrates at the same time and a substrate processing apparatus including the same.

The present invention also provides a substrate processing module in which a plurality of substrates are efficiently loaded and unloaded into/from a chamber and a substrate processing apparatus including the same.

Further another object of the present invention will become evident with reference to following detailed descriptions and accompanying drawings.

Embodiments of the present invention provide substrate processing modules including: a lower chamber having an opened upper portion, the lower chamber having a passage, through which a substrate is accessible, in a side thereof; a plurality of susceptors on which the substrate is placed on each of top surfaces thereof, the plurality of susceptors being disposed within the lower chamber and fixedly disposed around a preset center of the lower chamber; a rotation member disposed on the preset center of the lower chamber, the rotation member being rotatable with respect to the preset center; a plurality of holders connected to the rotation member and rotated together with the rotation member, the plurality of holders having at least one seat surface on which the substrate is placed; and a driving module connected to the rotation member, the driving module moving one of the holders to a transfer position corresponding to the passage by driving the rotation member.

In some embodiments, the driving module may elevate the rotation member to locate each of the holders at a receiving height or a loading height, and each of the holders may be disposed at a height higher than those of the susceptors at the receiving height, and the at least one seat surface of the holders may be disposed at a height lower than top surfaces of the susceptors at the loading height.

In other embodiments, each of the holders may be moved to the transfer position in a state where each of the holders is disposed at the receiving height.

In still other embodiments, each of the holders may include: a fork opened toward the outside of the lower chamber, the fork having an arc shape and a central angle of about 180 degrees or more; and at least one support tip connected to the fork to protrude inward from the fork, the support tip providing the seat surface, wherein each of the susceptors may have at least one insertion groove in which the support tip is inserted when each of the holders respectively disposed on the susceptors is moved to the loading height.

In even other embodiments, each of the susceptors may include: a heating plate; and a cover disposed on the heating plate, the cover having a support surface on which the substrate is placed, wherein the insertion groove may be defined in an edge of the support surface.

In yet other embodiments, the susceptors and the holders may be arranged at equiangular intervals with respect to the center, and the susceptors may have the same number as the holders.

In further embodiments, one of the susceptors may be disposed to correspond to the passage.

In still further embodiments, the lower chamber may include a plurality of exhaust ports disposed along an edge of a lower wall thereof, and the exhaust ports may be disposed outside the susceptors, respectively.

In even further embodiments, the substrate processing modules may further include: an upper chamber connected to an upper portion of the lower chamber, the upper chamber having an opening corresponding to the center; a cylinder having an opened lower portion connected to the opening of the upper chamber; a gas supply port connected to the cylinder to supply a process gas supplied from the outside into the cylinder; and an antenna surrounding the cylinder to generate an electric field within the cylinder.

In yet further embodiments, the lower chamber may have a plurality of openings respectively corresponding to the susceptors, and wherein the substrate processing modules may further include: showerheads, each having a buffer space recessed from a top surface thereof and a plurality of injection holes connected to the buffer space, the showerheads being disposed on the openings, respectively; and upper chambers respectively disposed above the showerheads to block the buffer space from the outside, the upper chambers having gas supply ports for supplying a process gas supplied from the outside into the buffer space, respectively.

In other embodiments of the present invention, substrate processing apparatuses include: a loadlock chamber in which a substrate transferred from the outside is placed, the loadlock chamber having the inside changed into a vacuum or atmosphere state; a substrate processing module in which a process with respect to the substrate is performed; and a substrate transfer module disposed between the loadlock chamber and the substrate processing module, the substrate transfer module including a substrate transfer robot for transferring the substrate between the loadlock chamber and the substrate processing module, wherein the substrate processing module includes: a lower chamber having an opened upper portion, the lower chamber having a passage, through which the substrate is accessible, in a side thereof; a plurality of susceptors on which the substrate is placed on each of top surfaces thereof, the plurality of susceptors being disposed within the lower chamber and fixedly disposed around a preset center of the lower chamber; a rotation member disposed on the preset center of the lower chamber, the rotation member being rotatable with respect to the preset center; a plurality of holders connected to the rotation member and rotated together with the rotation member, the plurality of holders having at least one seat surface on which the substrate is placed; and a driving module connected to the rotation member, the driving module moving one of the holders to a transfer position corresponding to the passage by driving the rotation member.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic view of a substrate processing apparatus according to an embodiment of the present invention;

FIG. 2 is a schematic view illustrating a substrate processing module of FIG. 1;

FIG. 3 is a view illustrating the inside of a lower chamber of FIG. 2;

FIG. 4 is a view illustrating a cover of FIG. 2;

FIG. 5 is a view illustrating a holder of FIG. 2;

FIGS. 6 and 7 are views illustrating an operation of the holder of FIG. 2;

FIG. 8 is a schematic view illustrating a modified example of the substrate processing module of the FIG. 2; and

FIG. 9 is a schematic view illustrating another modified example of the substrate processing module of the FIG. 2.

### DETAILED DESCRIPTION OF PREFERRED EMBODIMENTS

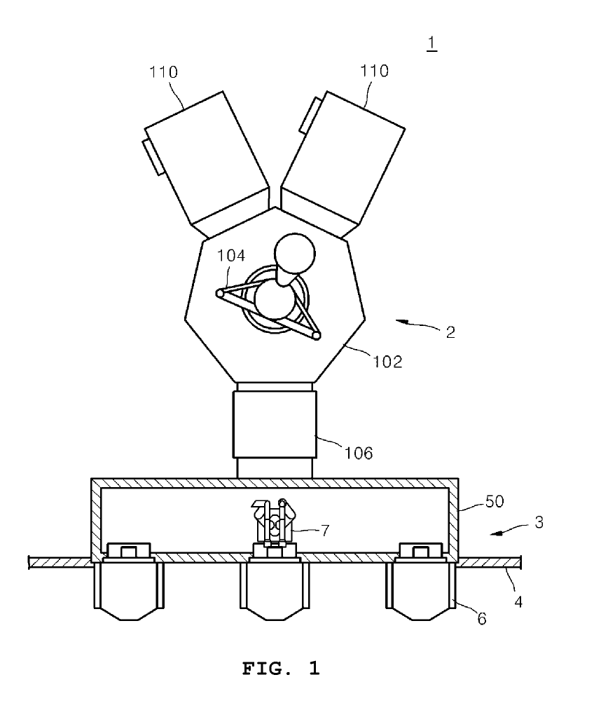

Hereinafter, exemplary embodiments of the present invention will be described in detail with reference to FIGS. 1 to 9. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

Although a deposition process is described below as an example, the present invention may be applied to various semiconductor manufacturing processes including the deposition process.

FIG. 1 is a schematic view of a substrate processing apparatus according to an embodiment of the present invention. A substrate processing apparatus 1 includes process equipment 2, an equipment front end module (EFEM) 3, and an interface wall 4. The EFEM 3 is mounted on a front side of the process equipment 2 to transfer a substrate between a container (not shown) in which substrate are received and the process equipment 2.

The EFEM 3 includes a plurality of loadports 6 and a frame 50. The frame 50 is disposed between the loadports 6 and the process equipment 2. The container in which the substrates are received is placed on the loadports 6 by a transfer unit (not shown) such as an overhead transfer, an overhead conveyor, or an automatic guided vehicle.

An airtight container such as a front open unified pod (FOUP) may be used as the container. A frame robot 7 for transferring the substrate between the container placed on the loadports 6 and the process equipment 2 is disposed within the frame 50. A door opener (not shown) for automatically opening or closing a door of the container may be disposed within the frame 50. Also, a fan filter unit (FEU) (not shown) for supplying clean air into the frame 50 may be provided within the frame 50 so that the clean air flows downward from an upper side within the frame 50.

A predetermined process with respect to the substrate is performed within the process equipment 2. The process equipment 2 includes a substrate transfer module 102, a loadlock chamber 106, and a substrate processing module 110. The substrate transfer module 102 has a substantially polygonal shape when viewed from an upper side. The loadlock chamber 106 and the substrate processing module 110 are disposed on a side surface of the substrate transfer module 102.

The loadlock chamber 106 is disposed on one side surface adjacent to the EFEM 3 among side surfaces of the substrate transfer module 102. The substrate is loaded to the process equipment 2 after the substrate is temporarily stayed within the loadlock chamber 106 so as to perform the process. After the process is completed, the substrate is unloaded from the process equipment 2 and then is temporarily stayed within the loadlock chamber 106. The insides of the substrate transfer module 102 and the substrate processing module 110 are maintained in vacuum states, respectively. The loadlock chamber 106 is converted into a vacuum or atmosphere state. The loadlock chamber 106 provides external contaminants from being introduced into the substrate transfer module 102 and the substrate processing module 110. Also, since the substrate is not exposed to the atmosphere during the transfer of the substrate, it may prevent an oxide layer form being grown on the substrate.

Gate valves (not shown) are disposed between the loadlock chamber 106 and the substrate transfer module 102 and between the loadlock chamber 106 and the EFEM 3, respectively. When the substrate is transferred between the EFEM 3 and the loadlock chamber 106, the gate valve disposed between the loadlock chamber 106 and the substrate transfer module 102 is closed. Also, when the substrate is transferred between the loadlock chamber 106 and the substrate transfer module 102, the gate valve disposed between the loadlock chamber 106 and the EFEM 3 is closed.

The substrate transfer module 102 includes a substrate transfer robot 104. The substrate transfer robot 104 transfers the substrate between the loadlock chamber 106 and the substrate processing module 110. The substrate transfer module 102 is sealed so that the substrate transfer module 102 is maintained in the vacuum state when the substrate is transferred. The maintenance of the vacuum state is for preventing the substrate from being exposed to contaminants (e.g., O₂, particle materials, and the like).

The substrate processing module 110 is provided to deposit a thin film on the substrate. Although two substrate processing modules 110 are illustrated in FIG. 1, the present invention is not limited thereto. For example, three or more substrate processing modules 110 may be provided. Also, a module for performing the other process (e.g., cleaning or etching process) may be disposed on the side surface of the substrate transfer module 102.

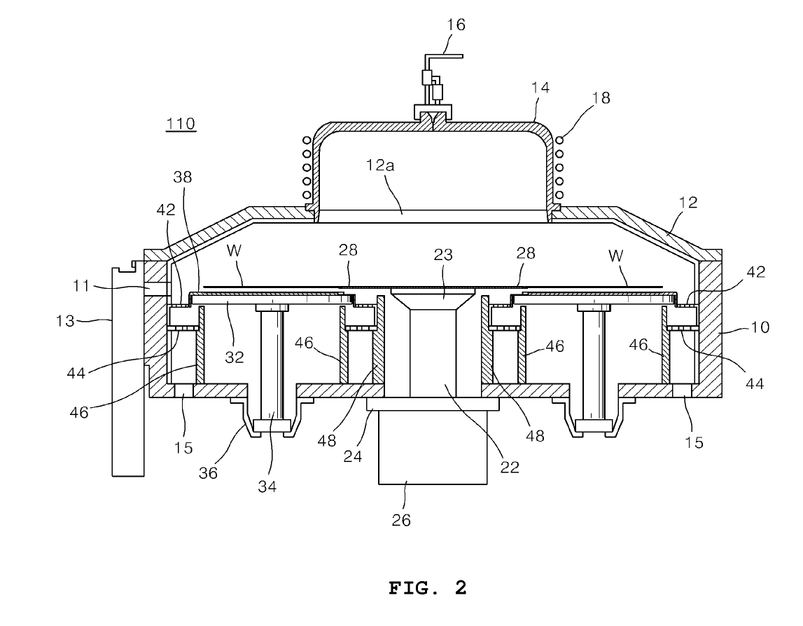

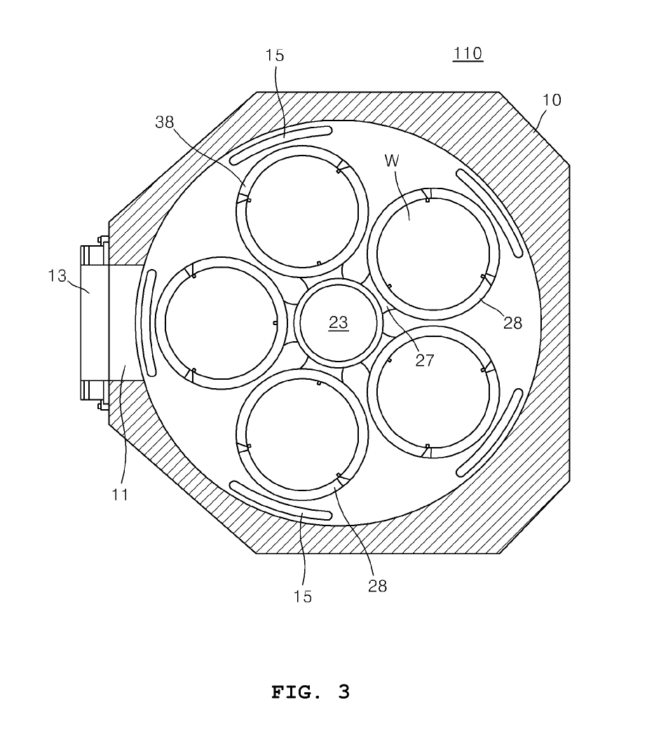

FIG. 2 is a schematic view illustrating the substrate processing module of FIG. 1. FIG. 3 is a view illustrating the inside of a lower chamber of FIG. 2. Referring to FIG. 2, the substrate processing module 110 includes a lower chamber 10, an upper chamber 12, and a cylinder 14. The lower chamber 10 and the upper chamber 12 provide a process space. A process with respect to a substrate W is performed within the process space. The cylinder 14 provides a generation space. Plasma is generated from a process gas supplied into the generation space.

The lower chamber 10 has an opened upper portion. The upper chamber 12 is connected to the upper portion of the lower chamber 10. The upper chamber 12 is inclined downward toward the outside. Also, the upper chamber 12 has an opening 12a in a center thereof. The cylinder 14 is disposed on the opening 12a. The cylinder 14 closes the opening 12a. The upper chamber 12 together with the cylinder 14 closes the opened upper portion of the lower chamber 10.

A gas supply port 16 is connected to an upper portion of the cylinder 14. The process gas is supplied into the cylinder 14 through the gas supply port 16. The process gas may be provided to deposit a thin film on a surface of the substrate W. Here, various gases may be used according to a kind of thin film. An antenna 18 has a coil shape to surround the outside of the cylinder 14. The antenna 18 is connected to an RF generator (not shown). Also, an RF matcher (not shown) may be disposed between the antenna 18 and the RF generator. When high frequency current flows into the antenna 18, a magnetic field is generated within the cylinder 14. Then, the process gas may be supplied into the cylinder 14 to generate plasma. The generated plasma is moved onto the surface of the substrate W placed on the susceptor to form a thin film.

The lower chamber 10 has a passage 11 in a side thereof. The substrate W is loaded into the lower chamber 10 through the passage 11. A gave valve 13 is disposed outside the passage 11. The passage 11 may be opened or closed by the gate valve 13. As described above, the substrate transfer robot 104 is moved together with the substrate W into the lower chamber 10 through the passage 11. Then, the substrate W is placed on a fork 28 that will be described later, and then is moved to the outside of the lower chamber 10 through the passage 11. Here, the passage 11 is opened by the gate valve 13.

As shown in FIG. 2, the susceptor is disposed inside the lower chamber 10. As described below, the susceptor includes a heating plate 32 and a cover 38. The substrate W is moved into the lower chamber 10 by the substrate transfer robot 104. When the process is performed, the substrate W is placed on a top surface of the susceptor. The susceptor is supported by a support shaft 34. The support shaft 34 is fixed to a lower portion of the lower chamber 10 through a bracket 36.

As shown in FIG. 3, the susceptors are fixedly disposed around a preset center of the lower chamber 10. The susceptors may be arranged at equiangular (e.g., about 72°) intervals. One of the susceptors may be disposed on a front side (that represents a direction of the substrate moved into the lower chamber 10 through the passage 11) of the passage 11. A process may start in a state where substrates W are respectively placed on all of the susceptors. Here, the process with respect to each of the substrates W may be performed at the same time. Thus, the process may be performed on five substrates W at a time to improve productivity.

As described above, the substrate W is moved into the lower chamber 10 by the substrate transfer robot 104. Then, the substrate transfer robot 104 puts down the substrate W on the fork 28.

A rotation member includes a rotation shaft 22 and a rotation plate 23. As shown in FIGS. 2 and 3, five forks 28 are connected to the rotation plate 23 through arms 27, respectively. Also, the forks 28 are arranged at equiangular (e.g., 72°) intervals with respect to a center (or the preset center of the lower chamber 10) of the rotation plate 23. The rotation plate 23 is connected to the rotation shaft 22. The rotation shaft 22 passes through a lower wall of the lower chamber 10. Also, the rotation shaft 22 is disposed on the preset center of the lower chamber 10 and rotated with respect to the preset center of the lower chamber 10. The rotation shaft 22 is connected to a driving module 26. The rotation shaft is elevated and rotated by the driving module 26. The rotation plate 22 is elevated and rotated together with the rotation shaft 22. The forks 28 are elevated and rotated together with the rotation plate 23. The driving module 26 is fixed to a support plate 24 fixedly disposed on the lower wall of the lower chamber 10.

The forks 28 may be disposed on the front side (“transfer position”) of the passage 11 by the rotation thereof. The substrate transfer robot 104 puts the substrate W on the fork 28 disposed at the transfer position. Here, the substrate W is placed on a top surface of a support tip 29 that will be described later. The fork 28 receiving the substrate W is rotated to leave from the transfer position. The next fork 28 in which the substrate W is not received is rotated and moved to the transfer position. In like manner, the substrate transfer robot 104 puts a substrate W on a fork 28 disposed at the transfer position. The forks 28 may be successively moved to the transfer position by the rotation of the rotation plate 23. Substrates W are successively placed on top surfaces of the forks 28. Through the above-described processes, the plurality of substrates W may be placed on the top surface of the forks 28.

Also, the substrate W may be placed on the susceptor or spaced from the susceptor by the elevation of the fork 28. A detailed description with respect to the elevation of the fork 28 will be described later.

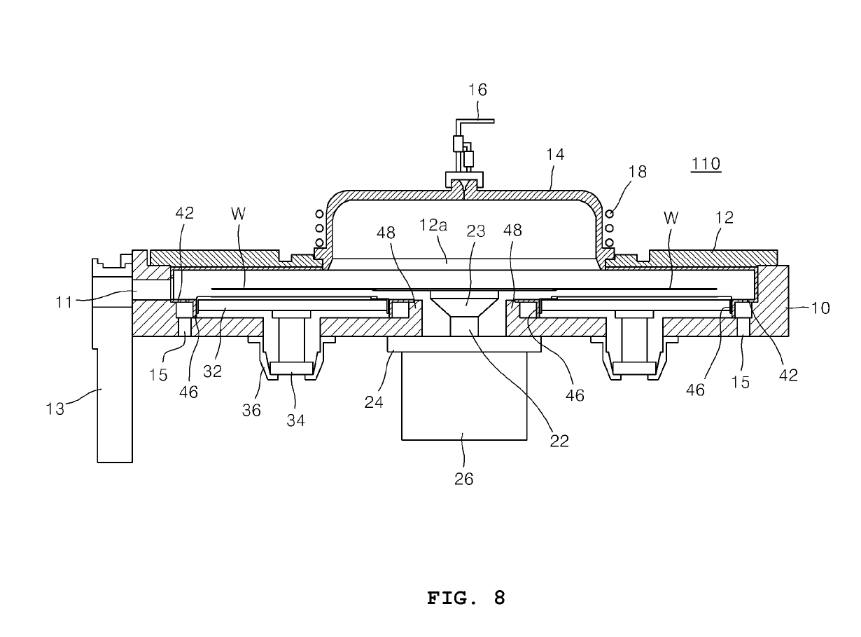

As shown in FIGS. 2 and 3, the lower chamber 10 includes exhaust ports 15 disposed in edge of a bottom surface thereof. The exhaust ports 15 are disposed outside the susceptors, respectively. The exhaust ports 15 has the same number as the susceptors. When a process is performed, byproducts and non-reaction gases are discharged to the outside of the lower chamber 10 through the exhaust ports 15. An upper baffle 42 and a lower baffle 44 are disposed around the susceptor. Supports 46 and 48 support the upper baffle 42 and the lower baffle 44. The upper baffle 42 and the lower baffle 44 have through-holes 42a and 44a (see FIGS. 7 and 8), respectively. The byproducts and the non-reaction gases are moved into the exhaust ports 15 through the through-holes 42a and 44a.

The susceptor includes the heating plate 32 and the cover 38. The heating plate 32 has a circular disk shape corresponding to that of the substrate W. The heating plate 32 heats the substrate W placed thereon to a process temperature when the process is performed. The cover 38 is disposed on the heating plate 32. However, unlike the current embodiment, the heating plate 32 and the cover 38 may be integrally manufactured.

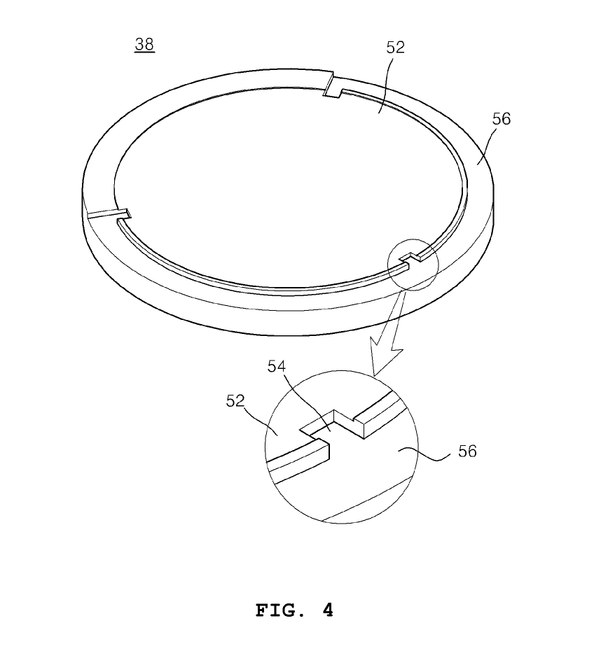

FIG. 4 is a view illustrating a cover of FIG. 2. The cover 38 has a support surface 52. The support surface 52 has substantially the same shape as the substrate W. An insertion groove 54 is recessed from the support surface 52. As described below, when a holder descends, the support tip 29 is inserted into the insertion groove 54. In like manner, a receiving groove 56 is recessed from the support surface 52. When the holder descends, the fork 28 is received into the receiving groove 56. The insertion groove 54 may have substantially the same size and shape as the support tip 29. The receiving groove 56 may have substantially the same size and shape as the fork 28.

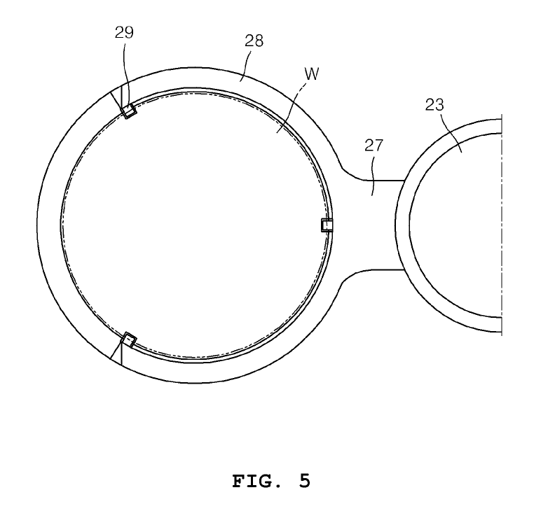

FIG. 5 is a view illustrating a holder of FIG. 2. The holder includes the fork 28 and the support tip 29. The fork 28 may have an arc shape with an inner diameter greater than a diameter of the substrate W. The fork 28 may have an arc shape with a central angle greater than about 180°. The support tip 29 is connected to the fork 28 to protrude inward from the fork 28. The support tip 29 is connected to a center and both ends of the fork 28. The substrate W placed on the holder is disposed inside the fork 28 and placed on a top surface (or a seat surface) of the support tip 29. The substrate W is stably supported by three support tips 29. Alternatively, the holder may have a shape different from that described in the current embodiment.

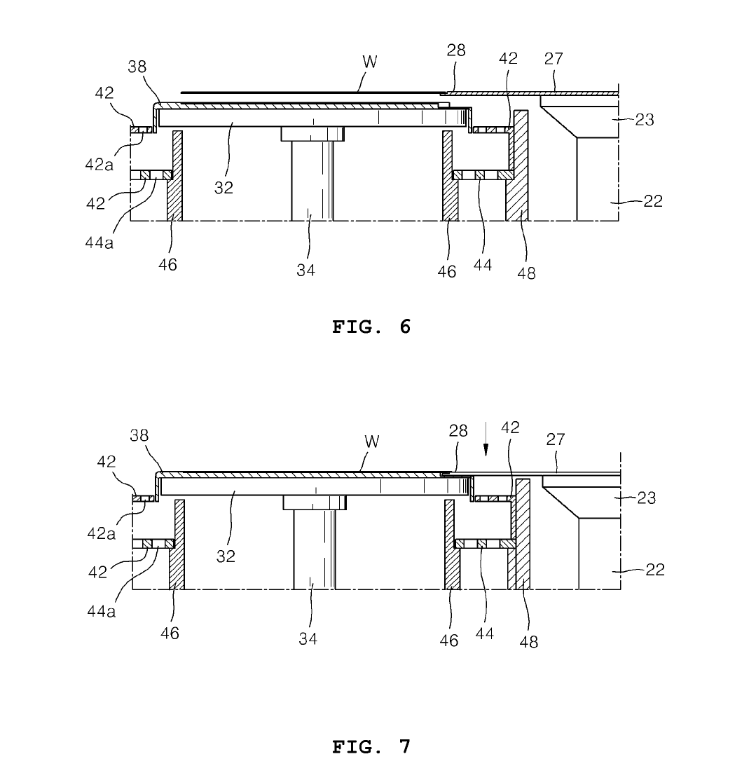

FIGS. 6 and 7 are views illustrating an operation of the holder of FIG. 2. Hereinafter, a method for placing a substrate W on the susceptor will be described with reference to FIGS. 6 and 7. Also, hereinafter, only one holder and susceptor will be described as an example. The following description may be equally applied to other holders and susceptors.

As described above, when one substrate W is placed on each of five holders, the substrate W is placed on the susceptor by the holder. Then, a process is performed on the respective substrates at the same time.

The fork 28 and the support tips 29 may elevated together with the rotation plate 23 by the driving module 26. Referring to FIG. 6, when the fork 28 ascends, the substrate W is placed on the support tips 29. Here, the fork 28 and the support tips 29 are disposed at positions (“receiving height”) higher than that of the susceptor. In a state where the fork 28 and the support tips 29 are disposed at the receiving height, the substrate W may be moved into the lower chamber 10 by the substrate transfer robot 104 and placed on the support tips 29. The substrate W placed on the support tips 29, may be moved to the outside of the lower chamber 10 by the substrate transfer robot 104. The substrate transfer robot 104 transfers the substrate W above the support tips 29 in a state where the substrate transfer robot 104 lifts the substrate W at a height higher than those of the support tips 29. Then, the substrate W may descend and be placed on the support tips 29. As described above, in a state where the fork 28 is disposed at the receiving height, the fork 28 may be rotated and moved to the transfer position.

Referring to FIG. 7, when the fork 28 descends, the substrate W is placed on the susceptor (or the cover 38). Here, the top surfaces (or the seat surfaces) of the support tips 29 may be disposed at positions (“loading height”) lower than that of the support surface 52 of the cover 38. The support tips 29 are inserted into the insertion groove 54, and the fork 28 is received into the receiving groove 56.

As described above, the substrate transfer robot 104 may successively transfer the plurality of substrates W on the respective holders. As the holders are moved at the loading height, the substrates W are placed on the respective susceptors at the same time. Thereafter, the process with respect to the respective substrates W is performed at the same time. When the process is completed, the holder is moved at the receiving height. Then, the substrate transfer robot 104 successively the substrates W placed on the respective holders. Here, the holders may be successively moved to the transfer position as described above.

FIG. 8 is a schematic view illustrating a modified example of the substrate processing module of the FIG. 2. Unlike FIG. 2, an upper chamber 12 may have a flat plate shape, and a lower baffle 44 may be removed. Descriptions omitted below may be substituted for the contents described above.

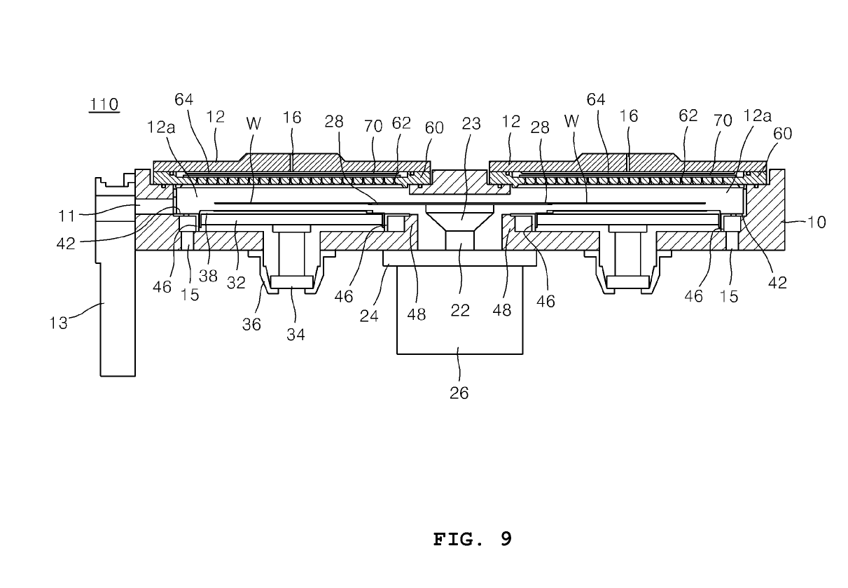

FIG. 9 is a schematic view illustrating another modified example of the substrate processing module of the FIG. 2. A lower chamber 10 has a plurality of openings 12a. The openings 12a are defined above a susceptor. The openings 12a may have the same number as the susceptor.

A showerhead 60 is disposed above each of the openings 12a. The showerhead 60 has a buffer space 64 recessed from a top surface thereof and a plurality of injection holes 62 connected to the buffer space 64. Upper chambers 12 are respectively disposed on the showerheads 60 to block the buffer space 64 from the outside. Each of the upper chambers 12 has a gas supply port 16. A process gas is supplied into the buffer space 64 through the gas supply port 16. The process gas may be provided to deposit a thin film on a surface of a substrate W. Here, various gases may be used according to a kind of thin film. A block plate 70 is disposed in the buffer space 64 and has a plurality of diffusion holes.

The process gas is supplied into the buffer space 64 through the gas supply port 16 and diffused through the block plate 70. Then, the process gas is supplied onto a top surface of the susceptor through the injection holes 62. The process gas is moved onto a top surface of the substrate W placed on each of susceptors to form the thin film on the surface of the substrate W.

According to the embodiment, the plurality of substrates may be efficiently loaded and unloaded into/from the chamber. Also, the process may be performed on the plurality of substrates at the same time.

Although the present invention is described in detail with reference to the exemplary embodiments, the invention may be embodied in many different forms. Thus, technical idea and scope of claims set forth below are not limited to the preferred embodiments.

What is claimed is:

1. A substrate processing module comprising:
a lower chamber having an opened upper portion, the lower chamber having a passage, through which a substrate is accessible, in a side thereof;
a plurality of susceptors on which the substrate is placed on each of top surfaces thereof, the plurality of susceptors being disposed within the lower chamber and fixedly disposed around a preset center of the lower chamber;
a rotation member disposed on the preset center of the lower chamber, the rotation member being rotatable with respect to the preset center;
a plurality of holders connected to the rotation member and rotated together with the rotation member, the plurality of holders having at least one seat surface on which the substrate is placed; and
a driving module connected to the rotation member, the driving module moving one of the holders to a transfer position corresponding to the passage by driving the rotation member.

2. The substrate processing module of claim 1, wherein the driving module elevates the rotation member to locate each of the holders at a receiving height or a loading height, and
each of the holders is disposed at a height higher than those of the susceptors at the receiving height, and the at least one seat surface of the holders is disposed at a height lower than top surfaces of the susceptors at the loading height.

3. The substrate processing module of claim 2, wherein each of the holders is moved to the transfer position in a state where each of the holders is disposed at the receiving height.

4. The substrate processing module of claim 2, wherein each of the holders comprises:
a fork opened toward the outside of the lower chamber, the fork having an arc shape and a central angle of about 180 degrees or more; and
at least one support tip connected to the fork to protrude inward from the fork, the support tip providing the seat surface,
wherein each of the susceptors has at least one insertion groove in which the support tip is inserted when each of the holders respectively disposed on the susceptors is moved to the loading height.

5. The substrate processing module of claim 4, wherein each of the susceptors comprises:
a heating plate; and
a cover disposed on the heating plate, the cover having a support surface on which the substrate is placed,
wherein the insertion groove is defined in an edge of the support surface.

6. The substrate processing module of claim 1, wherein the susceptors and the holders are arranged at equiangular intervals with respect to the center, and
the susceptors have the same number as the holders.

7. The substrate processing module of claim 6, wherein one of the susceptors is disposed to correspond to the passage.

8. The substrate processing module of claim 1, wherein the lower chamber comprises a plurality of exhaust ports disposed along an edge of a lower wall thereof, and
the exhaust ports are disposed outside the susceptors, respectively.

9. The substrate processing module of claim 1, further comprising:
an upper chamber connected to an upper portion of the lower chamber, the upper chamber having an opening corresponding to the center;
a cylinder having an opened lower portion connected to the opening of the upper chamber;
a gas supply port connected to the cylinder to supply a process gas supplied from the outside into the cylinder; and
an antenna surrounding the cylinder to generate an electric field within the cylinder.

10. The substrate processing module of claim 1, wherein the lower chamber has a plurality of openings respectively corresponding to the susceptors, and
wherein the substrate processing module further comprises:
showerheads, each having a buffer space recessed from a top surface thereof and a plurality of injection holes connected to the buffer space, the showerheads being disposed on the openings, respectively; and
upper chambers respectively disposed above the showerheads to block the buffer space from the outside, the upper chambers having gas supply ports for supplying a process gas supplied from the outside into the buffer space, respectively.

11. A substrate processing apparatus comprising:
a loadlock chamber in which a substrate transferred from the outside is placed, the loadlock chamber having the inside changed into a vacuum or atmosphere state;
a substrate processing module in which a process with respect to the substrate is performed; and
a substrate transfer module disposed between the loadlock chamber and the substrate processing module, the substrate transfer module comprising a substrate transfer robot for transferring the substrate between the loadlock chamber and the substrate processing module,
wherein the substrate processing module comprises:
a lower chamber having an opened upper portion, the lower chamber having a passage, through which the substrate is accessible, in a side thereof;
a plurality of susceptors on which the substrate is placed on each of top surfaces thereof, the plurality of susceptors being disposed within the lower chamber and fixedly disposed around a preset center of the lower chamber;
a rotation member disposed on the preset center of the lower chamber, the rotation member being rotatable with respect to the preset center;
a plurality of holders connected to the rotation member and rotated together with the rotation member, the plurality of holders having at least one seat surface on which the substrate is placed; and
a driving module connected to the rotation member, the driving module moving one of the holders to a transfer position corresponding to the passage by driving the rotation member.
